(19) United States
(12) Patent Application Publication
(10) Pub. No.: US 2011/0026229 A1
(43) Pub. Date: Feb. 3, 2011

(54) ELECTRONIC DEVICE HAVING CUSHIONING MEMBER

(76) Inventors: Wei-Kai Hsiao, Taoyuan Hsien (TW); Ming-Tang Yang, Taoyuan Hsien (TW)

Correspondence Address: AUSTIN RAPP & HARDMAN, 170 South Main Street, Suite 735, SALT LAKE CITY, UT, 84101, US

(21) Appl. No.: 12/690,841

(22) Filed: Jan. 20, 2010

(30) Foreign Application Priority Data
Jan. 20, 2009 (TW) 098102083

(51) Int. Cl. H05K 5/00

(52) U.S. Cl. 361/752

(57) ABSTRACT

An electronic device includes a casing, a circuit board and a cushioning member. The circuit board is disposed within the casing. The cushioning member is disposed within the casing and includes a sustaining element and a supporting element. The sustaining element is supported by the supporting element and disposed on the circuit board. When the casing is subject to an impact, the sustaining element is sustained against the casing to prevent from fracture of the casing.

### CLAIM OF PRIORITY

This application claims priority to Taiwanese Patent Application No. 098102083 filed on Jan. 20, 2009.

### FIELD OF THE INVENTION

The present invention relates to an electronic device, and more particularly to an electronic device having a cushioning member.

### BACKGROUND OF THE INVENTION

Recently, power adapters, chargers or power supply apparatuses become indispensable electronic devices for many kinds of electronic devices and communication devices. Take a power adapter for example. A closed space is defined within the casing of the power adapter for accommodating a circuit board. For reducing the overall volume of the power adapter, reducing the fabricating cost and enhancing the heat-dissipating efficacy, the thickness of the casing is gradually decreased. If the casing of the power adapter is too thin, the casing is readily fractured when the power adapter is suffered from an impact. When the casing is fractured, the safety distance between the circuit board within the casing and the external surrounding is usually insufficient. In addition, the foreign substance (e.g. water or dust) may enter the inner portion of the casing through the cracks of the casing. Under this circumstance, the circuit board is eventually damaged.

Therefore, there is a need of providing an electronic device having a cushioning member so as to obviate the drawbacks encountered from the prior art.

### SUMMARY OF THE INVENTION

The present invention provides an electronic device having a cushioning member for reducing deformation of the casing and minimizing the possibility of fracturing the casing.

In accordance with an aspect of the present invention, there is provided an electronic device. The electronic device includes a casing, a circuit board and a cushioning member. The circuit board is disposed within the casing. The cushioning member is disposed within the casing and includes a sustaining element and a supporting element. The sustaining element is supported by the supporting element and disposed on the circuit board. When the casing is subject to an impact, the sustaining element is sustained against the casing to prevent from fracture of the casing.

In accordance with another aspect of the present invention, there is provided a cushioning member for use in an electronic device including a casing and a circuit board. The circuit board and the cushioning member are disposed within the casing. The cushioning member includes a sustaining element and a supporting element. The supporting element is supported by the supporting element and disposed on the circuit board. When the casing is subject to an impact, the sustaining element is sustained against the casing to prevent from fracture of the casing.

The above contents of the present invention will become more readily apparent to those ordinarily skilled in the art after reviewing the following detailed description and accompanying drawings, in which:

### BRIEF DESCRIPTION OF THE DRAWINGS

FIG. 1A is a schematic exploded view illustrating an electronic device having a cushioning member according to a first embodiment of the present invention;

FIG. 1B is a schematic cross-sectional view of the electronic device of FIG. 1A taken along the line A-A′;

FIG. 1C is a schematic perspective view illustrating a portion of the electronic device as shown in FIG. 1A;

FIG. 2A is a schematic exploded view illustrating an electronic device having a cushioning member according to a second embodiment of the present invention;

FIG. 2B is a schematic cross-sectional view of the electronic device of FIG. 2A taken along the line A-A′;

FIG. 3A is a schematic exploded view illustrating an electronic device having a cushioning member according to a third embodiment of the present invention;

FIG. 3B is a schematic cross-sectional view of the electronic device of FIG. 3A taken along the line A-A′;

FIG. 4A is a schematic exploded view illustrating an electronic device having a cushioning member according to a fourth embodiment of the present invention;

FIG. 4B is a schematic cross-sectional view of the electronic device of FIG. 4A taken along the line A-A′;

FIG. 5A is a schematic exploded view illustrating an electronic device having a cushioning member according to a fifth embodiment of the present invention;

FIG. 5B is a schematic cross-sectional view of the electronic device of FIG. 5A taken along the line A-A′;

FIG. 6A is a schematic exploded view illustrating an electronic device having a cushioning member according to a sixth embodiment of the present invention;

FIG. 6B is a schematic cross-sectional view of the electronic device of FIG. 6A taken along the line A-A′;

FIG. 7A is a schematic exploded view illustrating an electronic device having a cushioning member according to a seventh embodiment of the present invention; and

FIG. 7B is a schematic cross-sectional view of the electronic device of FIG. 7A taken along the line A-A′.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

The present invention relates to an electronic device having a cushioning member. An example of the electronic device includes but is not limited to a power adapter, a charger or a power supply apparatus. The cushioning member is capable of providing a cushioning efficacy when the electronic device is suffered from an impact, thereby preventing from fracturing the electronic device.

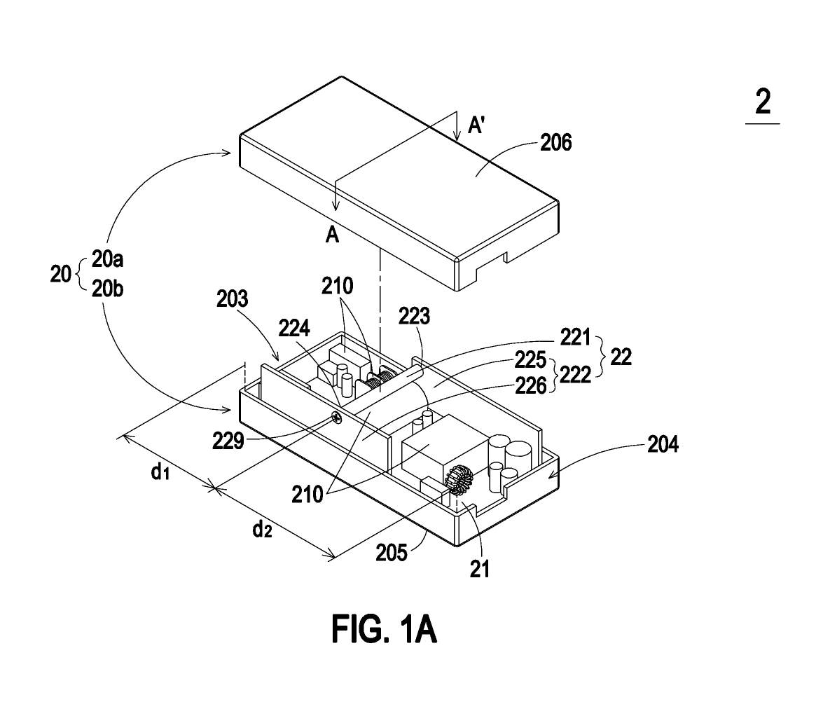

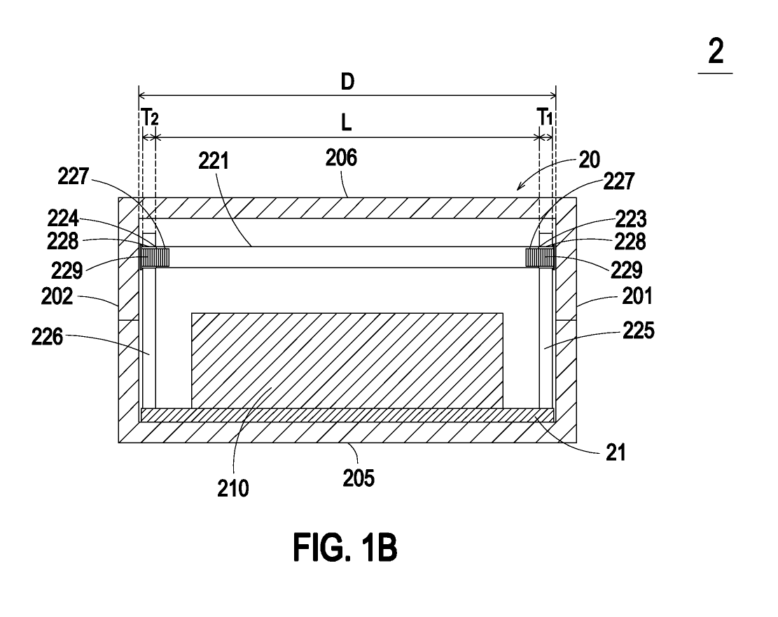

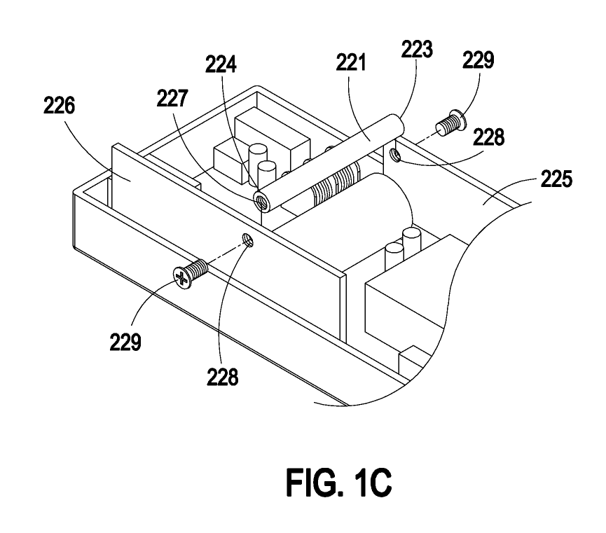

FIG. 1A is a schematic exploded view illustrating an electronic device having a cushioning member according to a first embodiment of the present invention. FIG. 1B is a schematic cross-sectional view of the electronic device of FIG. 1A taken along the line A-A′. Please refer to FIGS. 1A and 1B.

In this embodiment, the electronic device 2 is a power adapter. The electronic device 2 includes a casing 20, a circuit board 21 and a cushioning member 22. The circuit board 21 and the cushioning member 22 are disposed within the casing 20. The cushioning member 22 includes a sustaining element 221 and a supporting element 222. The sustaining element 221 is supported by the supporting element 222 and thus disposed on the circuit board 21. When the electronic device 2 is suffered from an impact, the sustaining element 221 of the cushioning member 22 is sustained against an inner wall of the casing 20 for providing a cushioning efficacy.

Hereinafter, the relation between the casing 20, the circuit board 21 and the cushioning member 22 of the electronic device 2 will be illustrated in more details with reference to FIGS. 1A and 1B.

As shown in FIGS. 1A and 1B, the casing 20 includes an upper casing part 20a and a lower casing part 20b. The upper casing part 20a and the lower casing part 20b are combined together by using an ultrasonic welding process or a screwing means. The circuit board 21 is supported by the lower casing part 20b. After the upper casing part 20a and the lower casing part 20b are combined together, the circuit board 21 and the electronic components on the circuit board 21 are accommodated within a closed space defined by the upper casing part 20a and the lower casing part 20b. In addition, the casing 20 includes a first side plate 201, a second side plate 202, a power input terminal surface 203, a power output terminal surface 204, a bottom plate 205 and a top plate 206. A power input terminal (not shown) is disposed on the power input terminal surface 203 for receiving external power (e.g. utility power). A power output terminal (not shown) is disposed on the power output terminal surface 204. After the utility power is received by the power input terminal, the utility power is converted into a regulated voltage by the electronic components 210 on the circuit board 21. The regulated voltage is transmitted to an external load (not shown) through the power output terminal. The bottom plate 205, the top plate 206, the first side plate 201 and the second side plate 202 are arranged between the power input terminal surface 203 and the power output terminal surface 204. In this embodiment, the first side plate 201 and the second side plate 202 are opposed to and parallel with each other; the power input terminal surface 203 and the power output terminal surface 204 are opposed to and parallel with each other; and the bottom plate 205 and the top plate 206 are opposed to and parallel with each other. The circuit board 21 is parallel with the bottom plate 205 and the top plate 206. That is, the first side plate 201 and the second side plate 202 are respectively disposed at two opposite sides of the circuit board 21, and the power input terminal surface 203 and the power output terminal surface 204 are respectively disposed at other two opposite sides of the circuit board 21. It is noted that, however, those skilled in the art will readily observe that numerous modifications and alterations of the locations of the casing 20 and the circuit board 21 may be made while retaining the teachings of the invention. It is found that the junctions between the upper casing part 20a and the lower casing part 20b of the casing 20 are relatively weaker. In particular, the first side plate 201 and the second side plate 202 are weaker than the power input terminal surface 203 and the power output terminal surface 204. For clarification and brevity, the present invention is illustrated by using the cushioning member 22 to prevent from fracture of the first side plate 201 or the second side plate 202.

The cushioning member 22 includes a sustaining element 221 and a supporting element 222. The sustaining element 221 is supported by the supporting element 222 and thus disposed on the circuit board 21. In this embodiment, the sustaining element 221 is a cylindrical rod, which has a first end 223 and a second end 224. In this embodiment, the supporting element 222 of the cushioning member 22 includes at least one metallic piece for dissipating heat. For example, the supporting element 222 includes a first metallic piece 225 and a second metallic piece 226. The first metallic piece 225 and the second metallic piece 226 of the supporting element 222 are respectively connected with the first end 223 and the second end 224 of the sustaining element 221.

FIG. 1C is a schematic perspective view illustrating a portion of the electronic device as shown in FIG. 1A. For facilitating the first end 223 and the second end 224 of the sustaining element 221 to be firmly fixed on the first metallic piece 225 and the second metallic piece 226 of the supporting element 222, the supporting element 222 further comprises fastening holes 227. In addition, the supporting element 222 has perforations 228 corresponding to the fastening holes 227. In this embodiment, the supporting element 222 comprises two fastening holes 227 at the first end 223 and the second end 224 of the sustaining element 221. The first metallic piece 225 and the second metallic piece 226 of the supporting element 222 have respective perforations 228 corresponding to the fastening holes 227 at the first end 223 and the second end 224 of the sustaining element 221. By penetrating fastening elements 229 (e.g. screws) through the perforations 228 and then screwing the fastening elements 229 in the fastening holes 227, the sustaining element 221 is fixed on the first metallic piece 225 and the second metallic piece 226 of the supporting element 222 (as shown in FIG. 1B). In this embodiment, the first metallic piece 225 and the second metallic piece 226 are opposed to and parallel with each other. Under this circumstance, the sustaining element 221 is perpendicular to the first metallic piece 225 and the second metallic piece 226 of the supporting element 222.

For achieving an excellent cushioning efficacy, the sustaining element 221 is perpendicular to the first side plate 201 and the second side plate 202 of the casing 20. In other words, after the first metallic piece 225 and the second metallic piece 226 of the supporting element 222 are fixed on the circuit board by adhering, fastening or inserting means for example, the first metallic piece 225 and the second metallic piece 226 of the supporting element 222 are substantially parallel with the first side plate 201 and the second side plate 202 of the casing 20. In addition, the first end 223 and the second end 224 of the sustaining element 221 are respectively disposed in the vicinity of the first side plate 201 and the second side plate 202 of the casing 20.

Generally, the electronic components 210 close to the power input terminal surface 203 are used to process higher-voltage signals but the electronic components 210 close to the power output terminal surface 204 are used to process lower-voltage signals. That is, the electronic components 210 close to the power input terminal surface 203 need to have a longer safety distance. For increasing the safety distance, the sustaining element 221 is disposed in the vicinity of the power input terminal surface 203. In other words, the distance d1 between the sustaining element 221 and the power input terminal surface 203 is smaller than the distance d1 between the sustaining element 221 and the power output terminal surface 204 (as shown in FIG. 1A). In addition, the distance D between the first side plate 201 and the second side plate 202 of the casing 20 is substantially equal to the sum of the length L of the sustaining element 221, the thickness T1 of the first metallic piece 225 and the thickness T2 of the second metallic piece 226. In other words, the first end 223 and the second end 224 of the sustaining element 221 are indirectly sustained against with the first side plate 201 and the second side plate 202 of the casing 20 (as shown in FIG. 1B).

When the electronic device 2 is suffered from an impact, the first end 223 and the second end 224 of the sustaining element 221 are indirectly sustained against the first side plate 201 and the second side plate 202 through the first metallic piece 225, the second metallic piece 226 and the fastening elements 229. Since the deformation of the first side plate 201 and the second side plate 202 that are relatively weaker are reduced by the cushioning member 22, the possibility of fracturing the electronic device is minimized and the electrical safety of the electronic device 2 is enhanced.

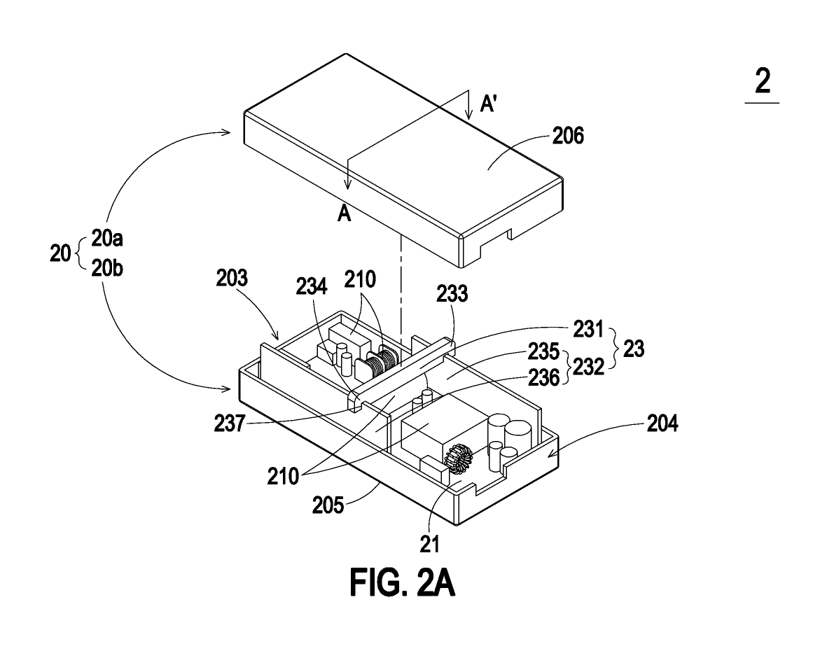

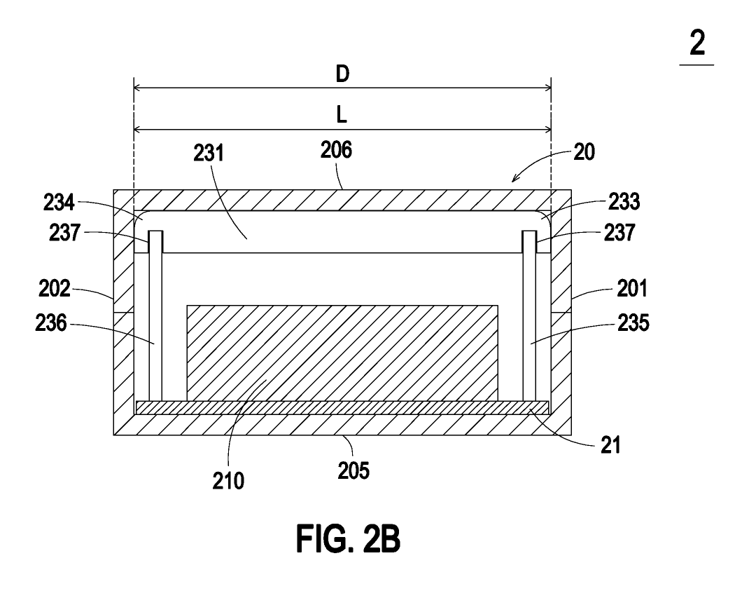

FIG. 2A is a schematic exploded view illustrating an electronic device having a cushioning member according to a second embodiment of the present invention. FIG. 2B is a schematic cross-sectional view of the electronic device of FIG. 2A taken along the line A-A′. Please refer to FIGS. 2A and 2B. In this embodiment, the electronic device 2 includes a casing 20, a circuit board 21 and a cushioning member 23. The casing 20 and the circuit board 21 included in the electronic device 2 are identical to those shown in FIGS. 1A and 1B, and are not redundantly described herein. The cushioning member 23 includes a sustaining element 231 and a supporting element 232. The sustaining element 231 is supported by the supporting element 232 and thus disposed on the circuit board 21. The supporting element 232 includes a first metallic piece 235 and a second metallic piece 236. The arrangements of the first metallic piece 235 and the second metallic piece 236 are identical to those illustrated in the first embodiment, and are not redundantly described herein.

In this embodiment, the sustaining element 231 is a rectangular rod, which has a first end 233 and a second end 234. In addition, the sustaining element 231 includes two grooves 237 at the first end 233 and the second end 234 of the sustaining element 231. The grooves 237 are engaged with the upper edges of the first metallic piece 235 and the second metallic piece 236, so that the sustaining element 231 is fixed on the first metallic piece 235 and the second metallic piece 236 of the supporting element 232. For enhancing fixing the sustaining element 231 on the first metallic piece 235 and the second metallic piece 236, the grooves 237 of the sustaining element 231 are dovetail grooves. Alternatively, the sustaining element 231 is integrally formed on the top plate 206 of the casing 20.

In this embodiment, the length L of the sustaining element 231 from the first end 233 to the second end 234 is substantially identical to the distance D between the first side plate 201 and the second side plate 202 (as shown in FIG. 2B). The arrangements of the casing 20, the circuit board 21 and the cushioning member 23 are identical to those illustrated in the first embodiment, and are not redundantly described herein. After the sustaining element 231 is supported by the supporting element 232 and disposed on the circuit board 21, the first end 233 and the second end 234 of the sustaining element 231 are in direct contact with the first side plate 201 and the second side plate 202, respectively. In other words, when the electronic device is suffered from an impact, the first end 233 and the second end 234 of the casing 20 are respectively sustained against the first side plate 201 and the second side plate 202 in order to reduce deformation of the casing 20 and prevent from fracture of the casing 20.

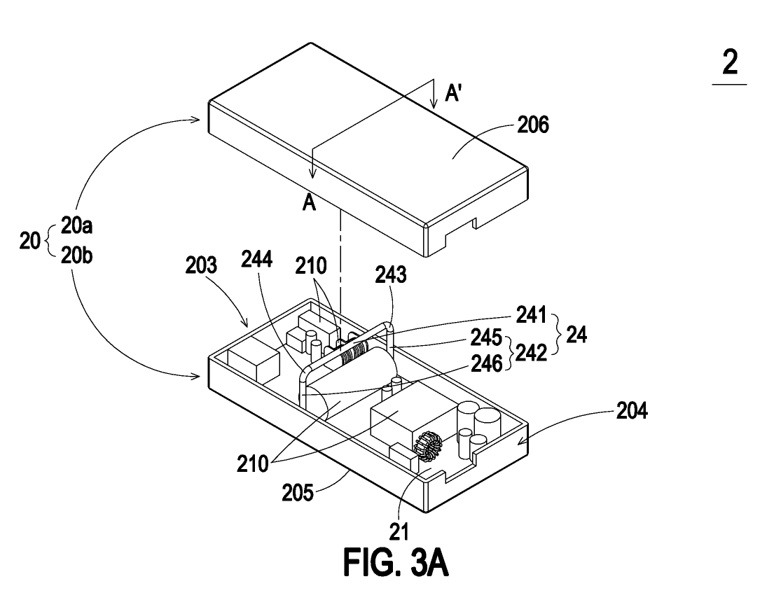

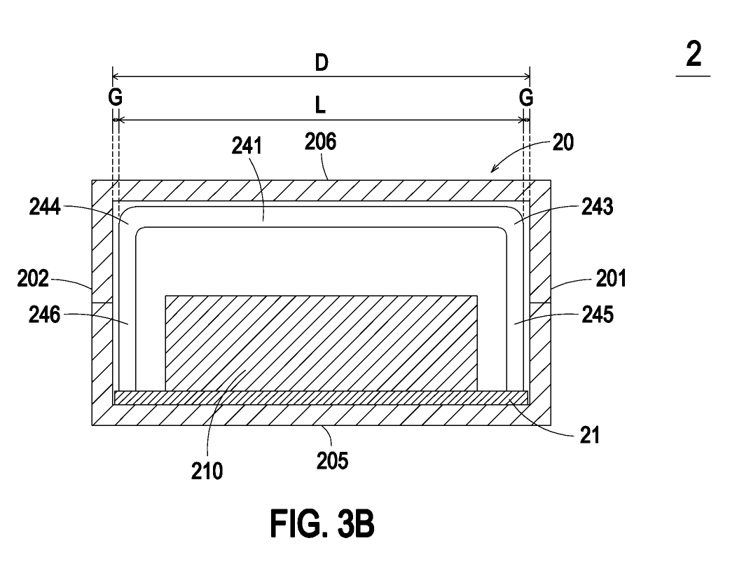

FIG. 3A is a schematic exploded view illustrating an electronic device having a cushioning member according to a third embodiment of the present invention. FIG. 3B is a schematic cross-sectional view of the electronic device of FIG. 3A taken along the line A-A′. Please refer to FIGS. 3A and 3B. In this embodiment, the electronic device 2 includes a casing 20, a circuit board 21 and a cushioning member 24. The casing 20 and the circuit board 21 included in the electronic device 2 are identical to those illustrated in the first and second embodiments, and are not redundantly described herein. The cushioning member 24 includes a sustaining element 241 and a supporting element 242. The sustaining element 241 is a cylindrical rod having a first end 243 and a second end 244. The supporting element 242 includes a first support post 245 and a second support post 246. The first support post 245 and the second support post 246 are connected with the first end 243 and the second end 244 of the sustaining element 241, respectively.

It is preferred that the sustaining element 241 and the supporting element 242 are integrally formed. That is, the first support post 245 and the second support post 246 are vertically extended from the first end 243 and the second end 244 of the sustaining element 241, respectively. As a consequence, the sustaining element 241 and the supporting element 242 collectively define a C-shaped structure (as shown in FIG. 3B). For enhancing the cushioning efficacy of the cushioning member 24, the sustaining element 241 is substantially perpendicular to the first side plate 201 and the second side plate 202 of the casing 20 when the sustaining element 241 is supported by the supporting element 242 and disposed on the circuit board 21.

In this embodiment, the length L of the sustaining element 241 from the first end 243 to the second end 244 is slightly smaller than the distance D between the first side plate 201 and the second side plate 202 (as shown in FIG. 3B). In other words, the first end 243 and the second end 244 of the sustaining element 241 are respectively spaced from the first side plate 201 and the second side plate 202 by a gap G. The gap G is smaller than the maximum allowable deformation of the first side plate 201 and the second side plate 202 of the casing 20. When the electronic device 2 is suffered from an impact, the first end 243 and the second end 244 of the sustaining element 241 are respectively sustained against the first side plate 201 and the second side plate 202 that are relatively weaker so as to reduce deformation of the casing 20 and prevent from fracture of the casing 20.

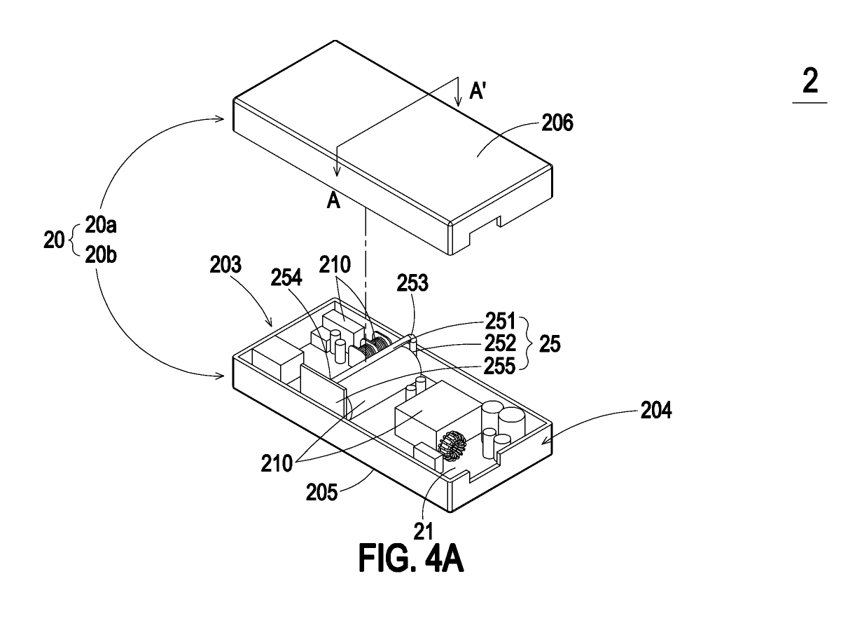

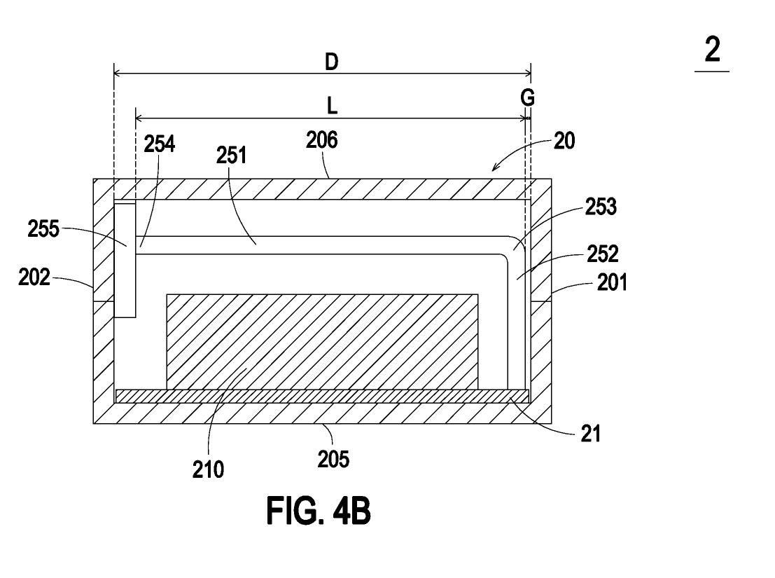

FIG. 4A is a schematic exploded view illustrating an electronic device having a cushioning member according to a fourth embodiment of the present invention. FIG. 4B is a schematic cross-sectional view of the electronic device of FIG. 4A taken along the line A-A′. Please refer to FIGS. 4A and 4B. In this embodiment, the electronic device 2 includes a casing 20, a circuit board 21 and a cushioning member 25. The casing 20 and the circuit board 21 included in the electronic device 2 are identical to those illustrated in the first and second embodiments, and are not redundantly described herein. The cushioning member 25 includes a sustaining element 251 and a supporting element 252. The sustaining element 251 is a cylindrical rod having a first end 253 and a second end 254. The supporting element 252 includes a support post, which is vertically extended from the first end 253 of the sustaining element 251 and disposed on the circuit board 21. The supporting element 252 further includes a sustaining surface 255. The second end 254 of the sustaining element 251 is sustained against the sustaining surface 255. The area of the sustaining surface 255 is greater than the cross-sectional area of the sustaining element 251. In addition, the supporting element 252 and the sustaining surface 255 are perpendicular to the sustaining element 251. Similarly, the sustaining element 251 is supported by the supporting element 252 and thus disposed on the circuit board 21.

For enhancing the cushioning efficacy of the cushioning member 25, the sustaining element 251 is substantially perpendicular to the first side plate 201 and the second side plate 202 of the casing 20. In this embodiment, the length L of the sustaining element 251 from the first end 253 to the second end 254 is smaller than the distance D between the first side plate 201 and the second side plate 202 (as shown in FIG. 4B). The second end 254 of the sustaining element 251 is sustained against the second side plate 202 via the sustaining surface 255. The first end 253 is spaced from the first side plate 201 by a gap G. The gap G is smaller than the maximum allowable deformation of the first side plate 201. When the electronic device 2 is suffered from an impact, the first end 253 and the sustaining surface 255 at the second end 254 of the sustaining element 251 are respectively sustained against the first side plate 201 and the second side plate 202 that are relatively weaker so as to reduce deformation of the casing 20 and prevent from fracture of the casing 20.

Alternatively, the locations of the supporting element 252 and the sustaining surface 255 may be exchanged. Under this circumstance, the supporting element 252 is vertically extended from the second end 254 of the sustaining element 251 and disposed on the circuit board 21; and the first end 253 of the sustaining element 251 is perpendicular to and sustained against the sustaining surface 255.

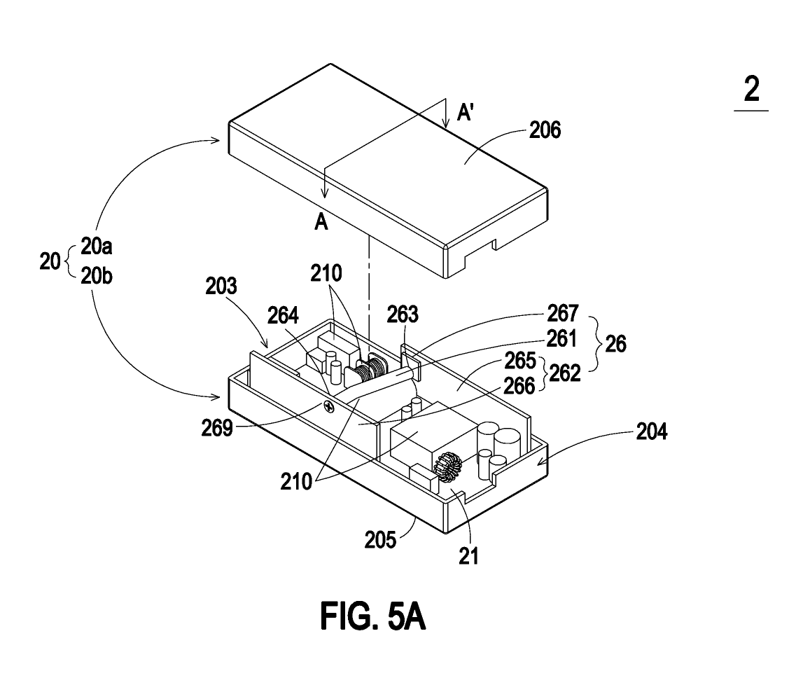

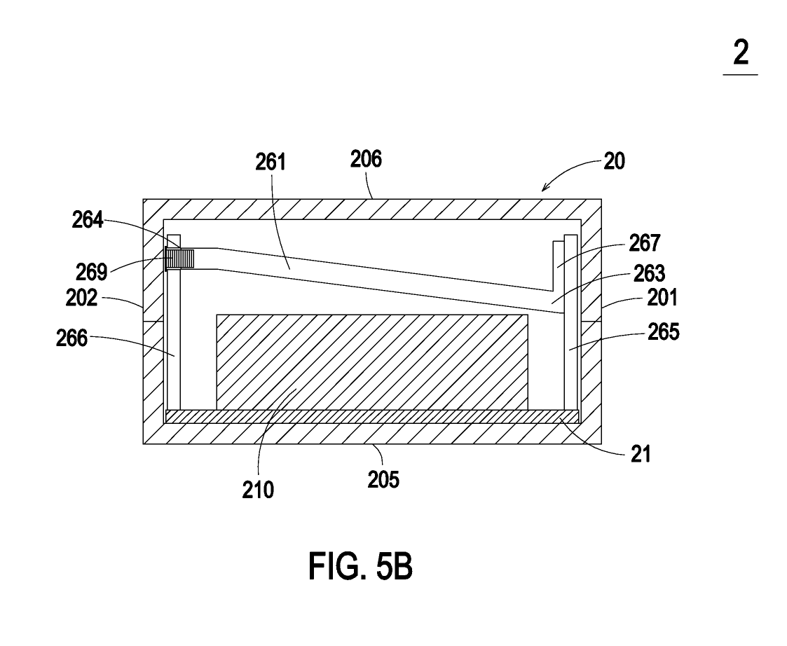

FIG. 5A is a schematic exploded view illustrating an electronic device having a cushioning member according to a fifth embodiment of the present invention. FIG. 5B is a schematic cross-sectional view of the electronic device of FIG. 5A taken along the line A-A′. Please refer to FIGS. 5A and 5B. In this embodiment, the electronic device 2 includes a casing 20, a circuit board 21 and a cushioning member 26. The casing 20 and the circuit board 21 included in the electronic device 2 are identical to those illustrated in the above embodiments, and are not redundantly described herein. The cushioning member 26 includes a sustaining element 261 and a supporting element 262. The sustaining element 261 is supported by the supporting element 262 and thus disposed on the circuit board 21. The supporting element 262 includes a first metallic piece 265 and a second metallic piece 266.

In this embodiment, the sustaining element 261 has a first end 263 and a second end 264. The second end 264 of the sustaining element 261 is fixed on the second metallic piece 266 of the sustaining element 261 by the fastening element 269 (e.g. a screw). The supporting element 262 further includes a sustaining surface 267. The first end 263 of the sustaining element 261 is sustained against the sustaining surface 267. It is preferred that the sustaining surface 267 and the first end 263 of the sustaining element 261 are integrally formed.

When the electronic device 2 is suffered from an impact, the first end 263 of the sustaining element 261 is indirectly sustained against the first side plate 201 through the sustaining surface 267 and the first metallic piece 265, and the second end 264 of the sustaining element 261 is indirectly sustained against the second side plate 202 through the second metallic piece 266 and the fastening element 269. As a consequence, the deformation of the casing 20 is reduced and the possibility of fracturing the casing 20 is minimized.

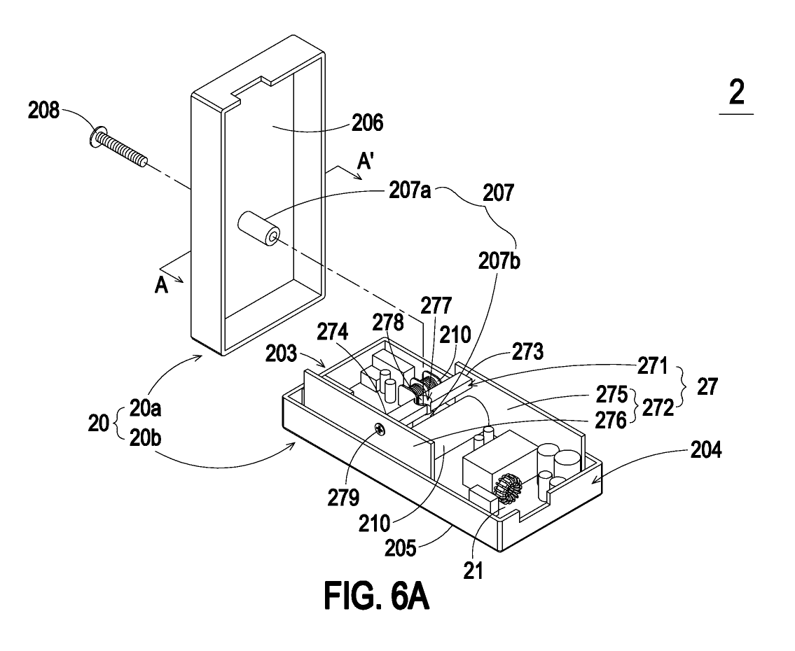

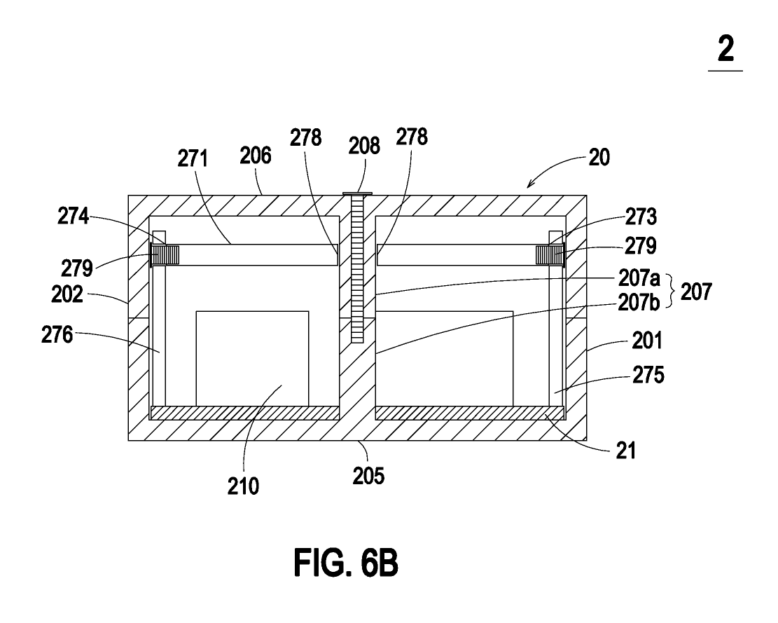

FIG. 6A is a schematic exploded view illustrating an electronic device having a cushioning member according to a sixth embodiment of the present invention. FIG. 6B is a schematic cross-sectional view of the electronic device of FIG. 6A taken along the line A-A′. Please refer to FIGS. 6A and 6B. In this embodiment, the electronic device 2 includes a casing 20, a circuit board 21 and a cushioning member 27. The casing 20 includes an upper casing part 20a and a lower casing part 20b. The upper casing part 20a and the lower casing part 20b are combined together by a screwing means. For example, the upper casing part 20a and the lower casing part 20b are combined together by a fastening element 208 (e.g. a screw). The casing 20 further includes a pillar member 207. The pillar member 207 includes a first pillar part 207a and a second pillar part 207b. The first pillar part 207a is vertically extended from a surface of the top plate 206. The first pillar part 207a has a threaded inner wall. The second pillar part 207b is vertically extended from a surface of the bottom plate 205. The second pillar part 207b also has a threaded inner wall.

Please refer to FIGS. 6A and 6B again. The cushioning member 27 includes a sustaining element 271 and a supporting element 272. The sustaining element 271 is supported by the supporting element 272 and thus disposed on the circuit board 21. The supporting element 272 includes a first metallic piece 275 and a second metallic piece 276. The arrangements of the first metallic piece 275 and the second metallic piece 276 are identical to those illustrated in the first embodiment, and are not redundantly described herein.

Corresponding to the pillar member 207 of the casing 20, a receiving part 277 is arranged between the first end 273 and the second end 274 of the sustaining element 271. In this embodiment, the receiving part 277 is a notch running through the sustaining element 271. By fastening elements 279 (e.g. screws), the first end 273 and the second end 274 of the sustaining element 271 are respectively fixed on the first metallic piece 275 and the second metallic piece 276 of the supporting element 272. The sustaining element 271 is supported by the supporting element 272 and thus disposed on the circuit board 21. The first end 273 of the sustaining element 271 is indirectly sustained against the first side plate 201 through the first metallic piece 275, and the second end 274 of the sustaining element 271 is indirectly sustained against the second side plate 202 through the second metallic piece 276. The pillar member 207 is sheathed by the inner wall 278 of the receiving part 277.

When the electronic device 2 is suffered from an impact, the inner wall 278 of the receiving part 277 is sustained against the pillar member 207 of the casing 20, and the first end 273 and the second end 274 of the sustaining element 271 are indirectly sustained against the first side plate 201 and the second side plate 202 through the first metallic piece 275, the second metallic piece 276 and the fastening elements 279. As a consequence, the possibility of fracturing the electronic device is minimized.

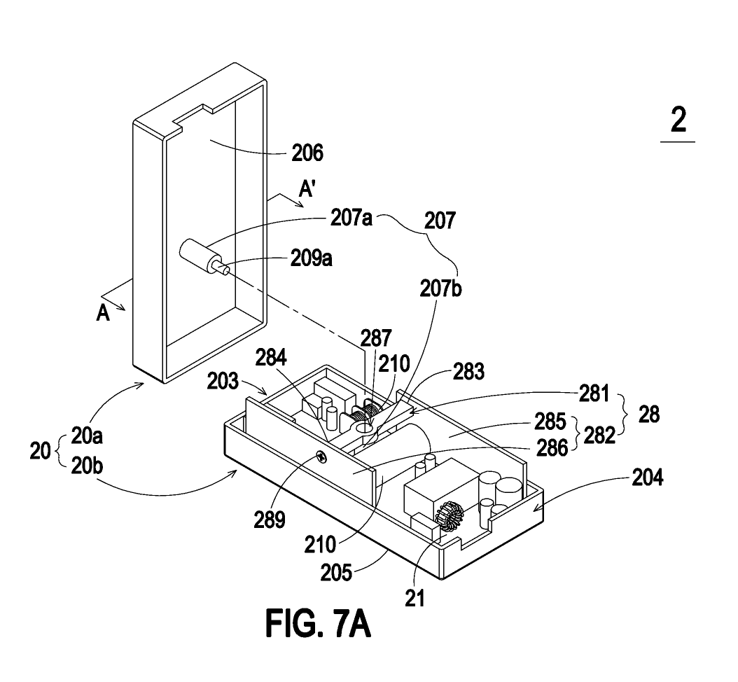

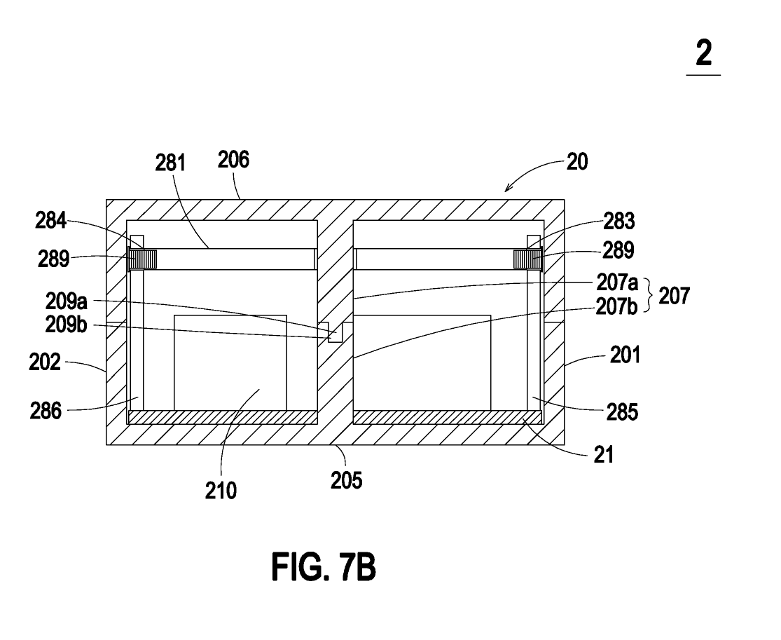

FIG. 7A is a schematic exploded view illustrating an electronic device having a cushioning member according to a seventh embodiment of the present invention. FIG. 7B is a schematic cross-sectional view of the electronic device of FIG. 7A taken along the line A-A′. Please refer to FIGS. 6A and 6B. In this embodiment, the electronic device 2 includes a casing 20, a circuit board 21 and a cushioning member 28. The casing 20 includes an upper casing part 20a and a lower casing part 20b. The casing 20 further includes a pillar member 207. The pillar member 207 includes a first pillar part 207a and a second pillar part 207b. The first pillar part 207a is vertically extended from a surface of the top plate 206. The second pillar part 207b is vertically extended from a surface of the bottom plate 205. In this embodiment, the first pillar part 207a has a protrusion 209a and the second pillar part 207b has an indentation 209b. After the protrusion 209a is engaged with the indentation 209b, the upper casing part 20a and the lower casing part 20b are combined together. Alternatively, the locations of the protrusion 209a and the indentation 209b may be exchanged.

The casing 20 and the circuit board 21 included in the electronic device 2 are identical to those illustrated in the above embodiments, and are not redundantly described herein. The cushioning member 28 includes a sustaining element 281 and a supporting element 282. The sustaining element 281 is supported by the supporting element 282 and thus disposed on the circuit board 21. The supporting element 282 includes a first metallic piece 285 and a second metallic piece 286. By fastening elements 289 (e.g. screws), the first end 283 and the second end 284 of the sustaining element 281 are respectively fixed on the first metallic piece 285 and the second metallic piece 286 of the supporting element 282. Corresponding to the pillar member 207 of the casing 20, a receiving part 287 is arranged between the first end 283 and the second end 284 of the sustaining element 281. In this embodiment, the receiving part 287 is a channel running through the sustaining element 281. The cross-sectional area of the receiving part 287 is slightly larger than the cross-sectional area of the pillar member 207, so that the pillar member 207 can be accommodated within the receiving part 287. The first end 283 of the sustaining element 281 is indirectly sustained against the first side plate 201 through the first metallic piece 285, and the second end 284 of the sustaining element 281 is indirectly sustained against the second side plate 202 through the second metallic piece 286.

In the above embodiments, the configurations of the cushioning members are diverse. For example, the supporting element includes heat-dissipating metallic piece (see FIGS. 1A, 2A, 5A, 6A and 7A) or a support post (see FIGS. 3A and 4A). Alternatively, both of the first end and the second end of the sustaining element are fixed on the supporting element (see FIGS. 1A, 2A, 3A, 6A and 7A). Alternatively, the first end or the second end of the sustaining element is fixed on the supporting element (see FIGS. 4A and 5A). Alternatively, the first end or the second end of the sustaining element is connected to a sustaining surface (see FIGS. 4A and 5A). The means for connecting the sustaining element with the supporting element is not restricted. For example, the sustaining element is connected with the supporting element by a fastening element (see FIGS. 1A, 5A, 6A and 7A). Alternatively, the groove of the sustaining element is engaged with the upper edge of the supporting element (see FIG. 2A). Alternatively, the sustaining element is integrated with the supporting element (see FIGS. 3A and 4A). The first end and the second end of the sustaining element can be directly sustained against the first side plate and the second side plate of the casing (see FIG. 2B), or indirectly sustained against the first side plate and the second side plate of the casing through the supporting element, the fastening element or the sustaining surface (see FIGS. 1B, 4B, 5B, 6B and 7B). Alternatively, the first end and the second end of the sustaining element is spaced from the first side plate and the second side plate of the casing by a gap that is smaller than the maximum allowable deformation of the casing (see FIGS. 3B and 4B). Since the first end and the second end of the sustaining element are directly or indirectly sustained against the casing, the deformation of the casing is reduced and the possibility of fracturing the casing is minimized.

In the first, second, third, fourth, sixth and seventh embodiments, the sustaining element is perpendicular to the first side plate and the second side plate of the casing to reduce the deformation on the first side plate and the second side plate. Alternatively, the sustaining element is not perpendicular to the first side plate and the second side plate of the casing (see FIG. 5A). In addition, the first end and the second end of the sustaining element can be directly or indirectly sustained against other weak sites of the casing according to the practical requirements. The shape of the sustaining element is not restricted as long as the sustaining element is supported by the supporting element and disposed on said circuit board for alleviating the deformation of the casing.

From the above description, the cushioning member is capable of alleviating the deformation of the casing when the electronic device is suffered from an impact, thereby minimizing the possibility of fracturing the casing. Since the first end and the second end of the sustaining element are directly or indirectly sustained against other weak sites of the casing, the deformation of the casing is reduced. It is noted that, however, those skilled in the art will readily observe that numerous modifications and alterations of the sustaining element and the supporting element may be made while retaining the teachings of the invention. Since the casing is protected by the cushioning member, the foreign substance (e.g. water or dust) is obstructed from entering the inner portion of the casing. Under this circumstance, the circuit board is well protected.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An electronic device comprising:
a casing;
a circuit board disposed within said casing; and
a cushioning member disposed within said casing and including a sustaining element and a supporting element, said sustaining element being supported by the supporting element and disposed on said circuit board, wherein when said casing is subject to an impact, said sustaining element is sustained against said casing to prevent from fracture of said casing.

2. The electronic device according to claim 1 wherein said cushioning member includes a heat-dissipating metallic piece or a support post.

3. The electronic device according to claim 1 wherein said sustaining element of said cushioning member has a first end and a second end.

4. The electronic device according to claim 3 wherein said first end and said second end of said sustaining element are connected to said supporting element.

5. The electronic device according to claim 4 wherein said casing further includes a pillar member, and said sustaining element further includes a receiving part between said first end and said second end of said sustaining element for accommodating said pillar member.

6. The electronic device according to claim 3 wherein one of said first end and said second end of said sustaining element is connected to said supporting element, and said sustaining element further includes a sustaining surface at the other one of said first end and said second end of said sustaining element.

7. The electronic device according to claim 3 wherein said first end and/or said second end of said sustaining element is fixed on said supporting element via a fastening element.

8. The electronic device according to claim 3 wherein said sustaining element further has grooves at said first end and said second end, and said grooves of said sustaining element are engaged with an upper edge of said supporting element such that said sustaining element is fixed on said supporting element.

9. The electronic device according to claim 3 wherein said supporting element is integrally extended from said first end and/or said second end of said sustaining element.

10. The electronic device according to claim 3 wherein said casing includes a first side plate and a second side plate, which are opposed to each other and respectively disposed in the vicinity of said first end and said second end of said sustaining element, wherein said first end and said second end of said sustaining element are directly or indirectly sustained against said first side plate and said second side plate of said casing when said casing is subject to an impact.

11. The electronic device according to claim 10 wherein said casing further includes a power input terminal surface and a power output terminal surface opposed to each other, said first side plate and said second side plate of said casing are arranged between said power input terminal surface and said power output terminal surface, and the distance between said sustaining element and said power input terminal surface is shorter than the distance between said sustaining element and said output terminal surface.

12. A cushioning member for use in an electronic device including a casing and a circuit board, said circuit board and said cushioning member being disposed within said casing, said cushioning member comprising:
a sustaining element; and
a supporting element supported by the supporting element and disposed on said circuit board, wherein when said casing is subject to an impact, said sustaining element is sustained against said casing to prevent from fracture of said casing.

13. The cushioning member according to claim 12 wherein said cushioning member includes a heat-dissipating metallic piece or a support post.

14. The cushioning member according to claim 12 wherein said sustaining element of said cushioning member has a first end and a second end.

15. The cushioning member according to claim 14 wherein said first end and said second end of said sustaining element are connected to said supporting element.

16. The cushioning member according to claim 15 wherein said casing further includes a pillar member, and said sustaining element further includes a receiving part between said first end and said second end of said sustaining element for accommodating said pillar member.

17. The cushioning member according to claim 14 wherein one of said first end and said second end of said sustaining element is connected to said supporting element, and said sustaining element further includes a sustaining surface at the other one of said first end and said second end of said sustaining element.

18. The cushioning member according to claim 14 wherein said first end and/or said second end of said sustaining element is fixed on said supporting element via a fastening element.

19. The cushioning member according to claim 14 wherein said sustaining element further has grooves at said first end and said second end, and said grooves of said sustaining element are engaged with an upper edge of said supporting element such that said sustaining element is fixed on said supporting element.

20. The cushioning member according to claim 14 wherein said supporting element is integrally extended from said first end and/or said second end of said sustaining element.
